(19) United States
(12) Patent Application Publication
(10) Pub. No.: US 2012/0126251 A1
(43) Pub. Date: May 24, 2012

(54) METHOD FOR MANUFACTURING SILICON CARBIDE SUBSTRATE, METHOD FOR MANUFACTURING SEMICONDUCTOR DEVICE, SILICON CARBIDE SUBSTRATE, AND SEMICONDUCTOR DEVICE

(75) Inventors: Makoto Sasaki, Itami-shi (JP); Shin Harada, Osaka-shi (JP); Takeyoshi Masuda, Osaka-shi (JP); Keiji Wada, Osaka-shi (JP); Hiroki Inoue, Itami-shi (JP); Taro Nishiguchi, Itami-shi (JP); Kyoko Okita, Itami-shi (JP); Yasuo Namikawa, Itami-shi (JP); Taku Horii, Osaka-shi (JP)

(73) Assignee: SUMITOMO ELECTRIC INDUSTRIES, LTD., Osaka-shi (JP)

(21) Appl. No.: 13/388,691

(22) PCT Filed: Feb. 25, 2011
(86) PCT No.: PCT/JP2011/054274

§ 371 Date: Feb. 3, 2012

(30) Foreign Application Priority Data
Jun. 4, 2010 (JP) 2010-128841

(51) Int. Cl. H01L 29/24; H01L 21/04

(52) U.S. Cl. 257/77; 438/458; 257/E29.104; 257/E21.054

(57) ABSTRACT

A method for manufacturing a silicon carbide substrate achieves reduced manufacturing cost. The method includes the steps of: preparing a base substrate and a SiC substrate; fabricating a stacked substrate by stacking the base substrate and the SiC substrate; fabricating a connected substrate by heating the stacked substrate; transferring a void, formed at a connection interface, in a thickness direction of the connected substrate by heating the connected substrate to cause the base substrate to have a temperature higher than that of the SiC substrate; and removing the void by removing a region including a main surface of the base substrate opposite to the SiC substrate.

### TECHNICAL FIELD

The present invention relates to a method for manufacturing a silicon carbide substrate, a method for manufacturing a semiconductor device, a silicon carbide substrate, and a semiconductor device, more particularly, a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

### BACKGROUND ART

In recent years, in order to achieve high breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

Under such circumstances, various silicon carbide crystals used in manufacturing of semiconductor devices and methods for manufacturing silicon carbide substrates have been considered and various ideas have been proposed (for example, see Japanese Patent Laying-Open No. 2002-280531 (Patent Literature 1)).

### CITATION LIST

### Patent Literature

PTL 1: Japanese Patent Laying-Open No. 2002-280531

### SUMMARY OF INVENTION

1. Technical Problem

However, silicon carbide does not have a liquid phase at an atmospheric pressure. In addition, crystal growth temperature thereof is 2000° C. or greater, which is very high. This makes it difficult to control and stabilize growth conditions. Accordingly, it is difficult for a silicon carbide single-crystal to have a large diameter while maintaining its quality to be high. Hence, it is not easy to obtain a high-quality silicon carbide substrate having a large diameter. This difficulty in fabricating such a silicon carbide substrate having a large diameter results in not only increased manufacturing cost of the silicon carbide substrate but also fewer semiconductor devices produced for one batch using the silicon carbide substrate. Accordingly, manufacturing cost of the semiconductor devices is increased, disadvantageously. It is considered that the manufacturing cost of the semiconductor devices can be reduced by effectively utilizing a silicon carbide single-crystal, which is high in manufacturing cost, as a substrate.

In view of this, an object of the present invention is to provide a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

2. Solution to Problem

A method for manufacturing a silicon carbide substrate in the present invention includes the steps of: preparing a base substrate made of silicon carbide and a SiC substrate made of single-crystal silicon carbide; fabricating a stacked substrate by stacking the base substrate and the SiC substrate such that main surfaces of the base substrate and the SiC substrate are in contact with each other; fabricating a connected substrate by heating the stacked substrate to connect the base substrate and the SiC substrate to each other; transferring a void in a thickness direction of the connected substrate by heating the connected substrate to form a temperature difference between the base substrate and the SiC substrate, the void being formed at an interface between the base substrate and the SiC substrate in the step of fabricating the connected substrate; and removing the void by removing a region including a main surface of one substrate of the base substrate and the SiC substrate, the one substrate being heated to have a higher temperature in the step of transferring the void, the main surface of the one substrate being opposite to the other substrate of the base substrate and the SiC substrate.

As described above, it is difficult for a high-quality silicon carbide single-crystal to have a large diameter. Meanwhile, for efficient manufacturing in a process of manufacturing a semiconductor device using a silicon carbide substrate, a substrate provided with predetermined uniform shape and size is required. Hence, even when a high-quality silicon carbide single-crystal (for example, silicon carbide single-crystal having a small defect density) is obtained, a region that cannot be processed into such a predetermined shape and the like by cutting, etc., may not be effectively used.

In contrast, in the method for manufacturing the silicon carbide substrate in the present invention, the silicon carbide substrate is manufactured by placing the SiC substrate made of single-crystal silicon carbide on the base substrate to fabricate the stacked substrate; and heating the stacked substrate so as to connect the base substrate and the SiC substrate to each other. Thus, the silicon carbide substrate can be manufactured, for example, in the following manner. That is, the base substrate formed of low-quality silicon carbide crystal having a large defect density is processed to have the predetermined shape and size. On such a base substrate, a high-quality silicon carbide single-crystal not shaped into the predetermined shape is placed as the SiC substrate. Then, they are heated. The silicon carbide substrate obtained in this way has the predetermined uniform shape and size as a whole. This contributes to improved efficiency in manufacturing semiconductor devices. Further, on the high-quality SiC substrate of such a silicon carbide substrate, an epitaxial growth layer is formed to manufacture a semiconductor device, for example. Thus, the silicon carbide single-crystal can be used effectively. As such, according to the method for manufacturing the silicon carbide substrate in the present invention, there can be manufactured a silicon carbide substrate that allows for reduced cost of manufacturing semiconductor devices using the silicon carbide substrate.

Further, when the connected substrate is fabricated by connecting the SiC substrate and the base substrate, the void may be formed at the interface between the base substrate and the SiC substrate due to warpage or the like of the SiC substrate and the base substrate. If the connected substrate thus having the void is used without any modification as the silicon carbide substrate for manufacturing of semiconductor devices, the void serves as a resistance component to increase resistivity of the substrate. This can disadvantageously increase on-resistance of a semiconductor device to be manufactured. Further, if the connected substrate thus having the void is used as the silicon carbide substrate without any modification, the existence of the void results in decreased strength of the substrate, whereby cracks are likely to be generated when being handled.

To address this, the method for manufacturing the silicon carbide substrate in the present invention includes the steps of: transferring the void in the thickness direction of the connected substrate after forming the connected substrate by connecting the SiC substrate and the base substrate to each other; and removing the void. Accordingly, voids in the silicon carbide substrate are reduced, thereby suppressing occurrence of the problem caused by the existence of the void. Here, the void can be removed by, for example, polishing. Further, the step of fabricating the connected substrate and the step of transferring the void may be performed as separate steps, but may be simultaneously performed as a single step. Specifically, for example, after the step of fabricating the stacked substrate, the stacked substrate may be heated to form a temperature difference between the base substrate and the SiC substrate, thereby transferring the void while connecting the base substrate and the SiC substrate to each other.

In the method for manufacturing the silicon carbide substrate, in the step of transferring the void, the connected substrate may be heated to cause the base substrate to have a temperature higher than that of the SiC substrate, and in the step of removing the void, the void may be removed by removing a region including a main surface of the base substrate opposite to the SiC substrate.

By heating the connected substrate to cause the base substrate to have a temperature higher than that of the SiC substrate, the void is transferred in the direction of the base substrate. Then, by removing the void together with the region including the main surface of the base substrate opposite to the SiC substrate, the void can be removed without consuming the SiC substrate. Accordingly, for example, in the case where a SiC substrate made of a high-quality single-crystal silicon carbide is adopted, the SiC substrate is never wasted in removing the void.

In the method for manufacturing the silicon carbide substrate, in the step of transferring the void, the main surface of the base substrate opposite to the SiC substrate may be heated to fall within a temperature range of not less than 1500° C. and not more than 3000° C.

With the heating temperature set at 1500° C. or greater, the void can be efficiently transferred. On the other hand, with the heating temperature set at 3000° C. or smaller, damages can be prevented from occurring upon etching the SiC substrate.

The above-described method for manufacturing the silicon carbide substrate may further include the step of smoothing the main surfaces of the base substrate and the SiC substrate before the step of fabricating the stacked substrate, the main surfaces of the base substrate and the SiC substrate being to be brought into contact with each other in the step of fabricating the stacked substrate. By smoothing the surfaces, which are to be the connection surface between the base substrate and the SiC substrate, the base substrate and the SiC substrate can be connected to each other more securely.

In the above-described method for manufacturing the silicon carbide substrate, the step of fabricating the stacked substrate may be performed without polishing the main surfaces of the base substrate and the SiC substrate before the step of fabricating the stacked substrate, the main surfaces of the base substrate and the SiC substrate being to be brought into contact with each other in the step of fabricating the stacked substrate. Accordingly, the manufacturing cost of the silicon carbide substrate can be reduced. Here, as described above, the main surfaces of the base substrate and the SiC substrate, which are to be brought into contact with each other in the step of fabricating the stacked substrate, may not be polished. However, for removal of damaged layers in the vicinity of surfaces formed by slicing upon fabricating the substrate, it is preferable to perform the step of fabricating the stacked substrate after performing a step of removing the damaged layers by means of etching, for example.

In the method for manufacturing the silicon carbide substrate, in the step of fabricating the stacked substrate, a plurality of the SiC substrates may be arranged side by side on the base substrate when viewed in a planar view. Explaining from a different point of view, the SiC substrates may be placed and arranged on and along the main surface of the base substrate.

As described above, it is difficult for a high-quality silicon carbide single-crystal to have a large diameter. To address this, the plurality of SiC substrates each obtained from a high-quality silicon carbide single-crystal are placed and arranged side by side when viewed in a planar view, and then the base substrate and the SiC substrates are connected to one another, thereby obtaining a silicon carbide substrate that can be handled as a substrate having a high-quality SiC layer and a large diameter. By using such a silicon carbide substrate, the process of manufacturing a semiconductor device can be improved in efficiency. It should be noted that in order to improve the efficiency of the process of manufacturing a semiconductor device, it is preferable that adjacent ones of the plurality of SiC substrates are arranged in contact with one another. More specifically, for example, the plurality of SiC substrates are preferably arranged in contact with one another in the form of a matrix when viewed in a planar view.

In the method for manufacturing the silicon carbide substrate, in the step of fabricating the stacked substrate, the SiC substrate may have a main surface opposite to the base substrate and having an off angle of not less than 50° and not more than 65° relative to a {0001} plane.

By growing single-crystal silicon carbide of hexagonal system in the <0001> direction, a high-quality single-crystal can be fabricated efficiently. From such a silicon carbide single-crystal grown in the <0001> direction, a silicon carbide substrate having a main surface corresponding to the {0001} plane can be obtained efficiently. Meanwhile, by using a silicon carbide substrate having a main surface having an off angle of not less than 50° and not more than 65° relative to the plane orientation of {0001}, a semiconductor device with high performance may be manufactured.

Specifically, for example, it is general that a silicon carbide substrate used in fabricating a MOSFET (Metal Oxide Semiconductor Field Effect Transistor) has a main surface having an off angle of approximately 8° or smaller relative to the plane orientation of {0001}. An epitaxial growth layer is formed on this main surface and an oxide film, an electrode, and the like are formed on this epitaxial growth layer, thereby obtaining a MOSFET. In this MOSFET, a channel region is formed in a region including an interface between the epitaxial growth layer and the oxide film. However, in the MOSFET having such a structure, a multiplicity of interface states are formed around the interface between the epitaxial growth layer and the oxide film, i.e., the location in which the channel region is formed, due to the substrate's main surface having an off angle of approximately 8° or smaller relative to the {0001} plane. This hinders traveling of carriers, thus decreasing channel mobility.

To address this, in the step of fabricating the stacked substrate, the SiC substrate has a main surface opposite to the base substrate and having an off angle of not less than 50° and not more than 65° relative to a {0001} plane, whereby the main surface of the silicon carbide substrate to be manufactured will have an off angle of not less than 50° and not more than 65° relative to the {0001} plane. This reduces the formation of the interface states. Accordingly, a silicon carbide substrate can be manufactured which allows for fabrication of a MOSFET or the like having reduced on-resistance.

In the method for manufacturing the silicon carbide substrate, in the step of fabricating the stacked substrate, the main surface of the SiC substrate opposite to the base substrate may have an off orientation forming an angle of 5° or smaller relative to a <1-100> direction.

The <1-100> direction is a representative off orientation in a silicon carbide substrate. Variation in the off orientation resulting from variation in a slicing process of the process of manufacturing the substrate is adapted to be 5° or smaller, which allows an epitaxial growth layer to be formed readily on the silicon carbide substrate.

In the above-described method for manufacturing the silicon carbide substrate, in the step of fabricating the stacked substrate, the main surface of the SiC substrate opposite to the base substrate may have an off angle of not less than −3° and not more than 5° relative to a {03-38} plane in the <1-100> direction.

Accordingly, channel mobility can be further improved in the case where a MOSFET is fabricated using the silicon carbide substrate. Here, setting the off angle at not less than −3° and not more than +5° relative to the plane orientation of {03-38} is based on a fact that particularly high channel mobility was obtained in this set range as a result of inspecting a relation between the channel mobility and the off angle.

Further, the “off angle relative to the {03-38} plane in the <1-100> direction” refers to an angle formed by an orthogonal projection of a normal line of the above-described main surface to a flat plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction.

It should be noted that the main surface preferably has a plane orientation of substantially {03-38}, and the main surface more preferably has a plane orientation of {03-38}. Here, the expression “the main surface has a plane orientation of substantially {03-38}” is intended to encompass a case where the plane orientation of the main surface of the substrate is included in a range of off angle such that the plane orientation can be substantially regarded as {03-38} in consideration of processing accuracy of the substrate. In this case, the range of off angle is, for example, a range of off angle of ±2° relative to {03-38}. Accordingly, the above-described channel mobility can be further improved.

In the method for manufacturing the silicon carbide substrate, in the step of fabricating the stacked substrate, the main surface of the SiC substrate opposite to the base substrate may have an off orientation forming an angle of 5° or smaller relative to a <11-20> direction.

The <11-20> direction is a representative off orientation in a silicon carbide substrate, as with the <1-100> direction. Variation in the off orientation resulting from variation in the slicing process of the process of manufacturing the substrate is adapted to be ±5°, which allows an epitaxial growth layer to be formed readily on the SiC substrate.

In the above-described method for manufacturing the silicon carbide substrate, in connecting the base substrate and the SiC substrate, the stacked substrate may be heated in an atmosphere obtained by reducing pressure of atmospheric air. Accordingly, the manufacturing cost of the silicon carbide substrate can be reduced.

In the method for manufacturing the silicon carbide substrate, in connecting the base substrate and the SiC substrate, the stacked substrate may be heated under a pressure higher than 10⁻¹ Pa and lower than 10⁴ Pa.

This can accomplish the above-described connection using a simple device, and provide an atmosphere for accomplishing the connection for a relatively short time. As a result, the manufacturing cost of the silicon carbide substrate can be reduced.

A method for manufacturing a semiconductor device in the present invention includes the steps of: preparing a silicon carbide substrate; forming an epitaxial growth layer on the silicon carbide substrate; and forming an electrode on the epitaxial growth layer. In the step of preparing the silicon carbide substrate, the silicon carbide substrate is manufactured using the above-described method for manufacturing the silicon carbide substrate in the present invention.

According to the method for manufacturing the semiconductor device in the present invention, the semiconductor device is manufactured using the silicon carbide substrate manufactured using the above-described method for manufacturing the silicon carbide substrate in the present invention. Accordingly, the manufacturing cost of the semiconductor device can be reduced.

A silicon carbide substrate according to the present invention is manufactured using the above-described method for manufacturing the silicon carbide substrate in the present invention. Accordingly, the silicon carbide substrate in the present invention allows for reduced cost in manufacturing semiconductor devices using the silicon carbide substrate.

A semiconductor device according to the present invention is manufactured using the method for manufacturing the semiconductor device of the present invention. Accordingly, the semiconductor device of the present invention is a semiconductor device manufactured with reduced cost.

### ADVANTAGEOUS EFFECTS OF INVENTION

As apparent from the description above, according to the method for manufacturing the silicon carbide substrate, the method for manufacturing the semiconductor device, the silicon carbide substrate, and the semiconductor device in the present invention, there can be provided a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

### BRIEF DESCRIPTION OF DRAWINGS

FIG. 1 is a flowchart schematically showing a method for manufacturing a silicon carbide substrate in a first embodiment.

FIG. 2 is a schematic cross sectional view for illustrating the method for manufacturing the silicon carbide substrate in the first embodiment.

FIG. 3 is a schematic cross sectional view for illustrating the method for manufacturing the silicon carbide substrate in the first embodiment.

FIG. 4 is an enlarged schematic partial cross sectional view showing a vicinity of voids shown in FIG. 3.

FIG. 5 is a schematic cross sectional view for illustrating the method for manufacturing the silicon carbide substrate in the first embodiment.

FIG. 6 is a schematic cross sectional view for illustrating the method for manufacturing the silicon carbide substrate in the first embodiment.

FIG. 7 is a schematic cross sectional view showing the structure of the silicon carbide substrate in the first embodiment.

FIG. 8 is a schematic cross sectional view for illustrating a method for manufacturing a silicon carbide substrate in a second embodiment.

FIG. 9 is a schematic cross sectional view for illustrating the method for manufacturing the silicon carbide substrate in the second embodiment.

FIG. 10 is a schematic cross sectional view for illustrating the method for manufacturing the silicon carbide substrate in the second embodiment.

FIG. 11 is a schematic cross sectional view showing the structure of the silicon carbide substrate in the second embodiment.

FIG. 12 is a schematic cross sectional view showing a structure of a vertical type MOSFET.

FIG. 13 is a flowchart schematically showing a method for manufacturing the vertical type MOSFET.

FIG. 14 is a schematic cross sectional view for illustrating the method for manufacturing the vertical type MOSFET.

FIG. 15 is a schematic cross sectional view for illustrating the method for manufacturing the vertical type MOSFET.

FIG. 16 is a schematic cross sectional view for illustrating the method for manufacturing the vertical type MOSFET.

FIG. 17 is a schematic cross sectional view for illustrating the method for manufacturing the vertical type MOSFET.

### DESCRIPTION OF EMBODIMENTS

The following describes embodiments of the present invention with reference to figures. It should be noted that in the below-mentioned figures, the same or corresponding portions are given the same reference characters and are not described repeatedly.

### First Embodiment

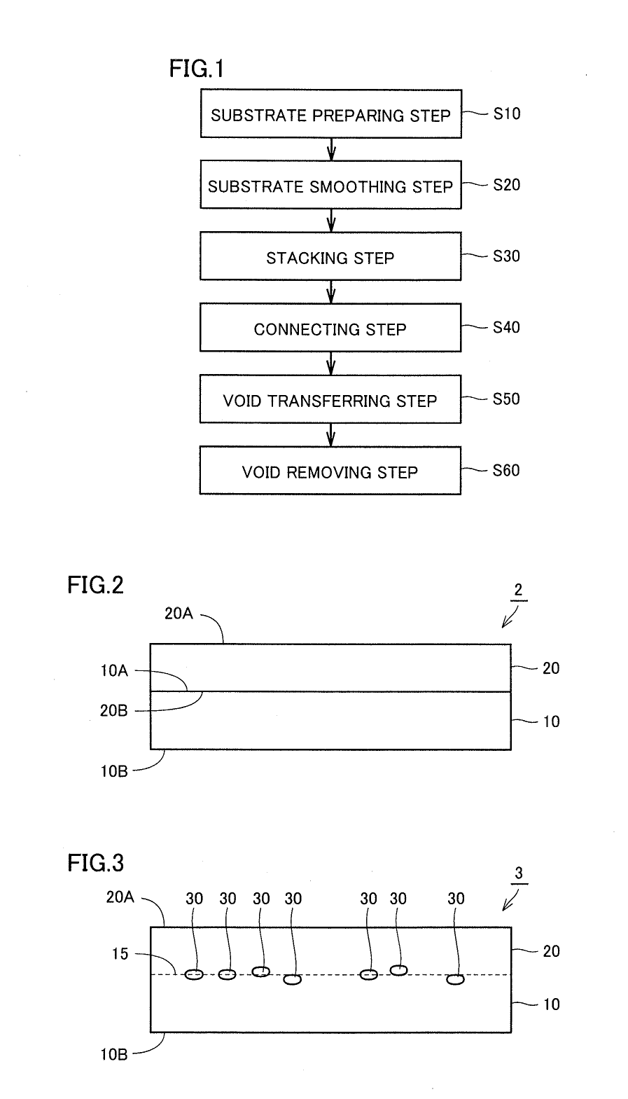

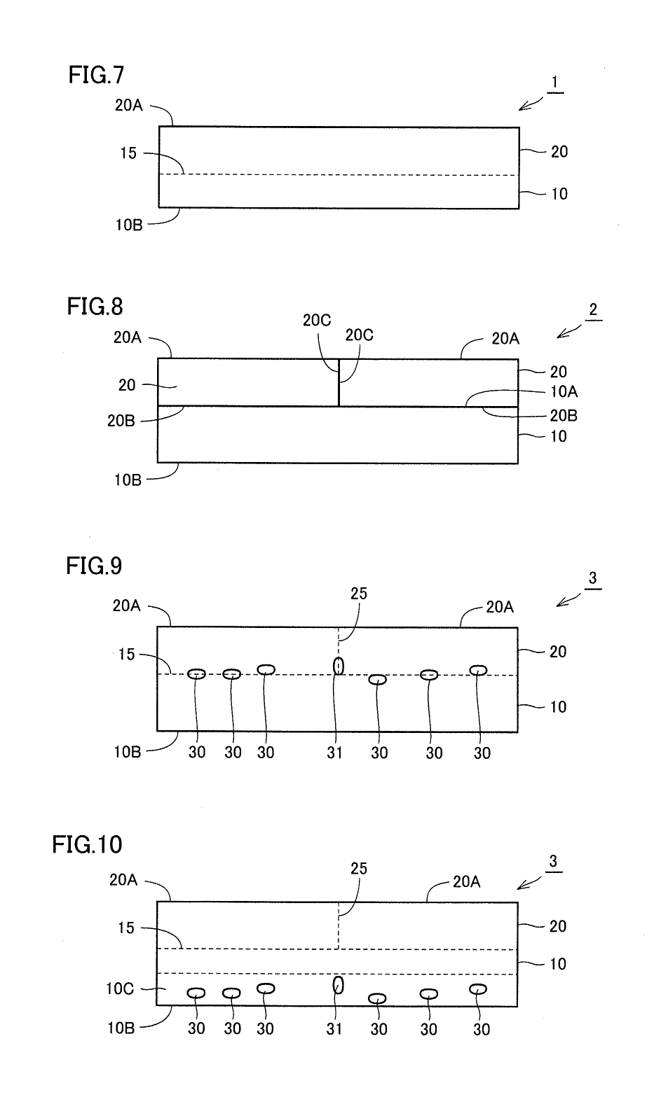

First, one embodiment, i.e., a first embodiment of the present invention will be described with reference to FIG. 1 to FIG. 7. Referring to FIG. 1, in a method for manufacturing a silicon carbide substrate in the present embodiment, first, as a step (S10), a substrate preparing step is performed. In this step (S10), referring to FIG. 2, for example, a base substrate 10 formed of silicon carbide and a SiC substrate 20 formed of single-crystal silicon carbide are prepared. SiC substrate 20 has a main surface 20A, which will be main surface 20A of a SiC layer 20 that will be obtained by this manufacturing method (see FIG. 7 described below). Hence, on this occasion, the plane orientation of main surface 20A of SiC substrate 20 is selected in accordance with desired plane orientation of main surface 20A.

Meanwhile, a substrate having an impurity concentration greater than, for example, 2×10¹⁹ cm⁻³ is adopted as base substrate 10. As SiC substrate 20, a substrate can be adopted which has an impurity concentration greater than 5×10¹⁸ cm⁻³ and smaller than 2×10¹⁹ cm⁻³. In this way, base layer 10 having a small resistivity can be formed while restraining generation of stacking fault at least in SiC layer 20 when providing heat treatment in a device process. Further, as base substrate 10, a substrate can be adopted which is formed of single-crystal silicon carbide, polycrystal silicon carbide, amorphous silicon carbide, a silicon carbide sintered compact, or the like.

Next, a substrate smoothing step is performed as a step (S20). In this step (S20), a main surface 10A of base substrate 10 and a main surface 20B of SiC substrate 20 (connection surface) are smoothed by, for example, polishing. Main surface 10A and main surface 20B are to be brought into contact with each other in a below-described step (S30). It should be noted that this step (S20) is not an essential step, but provides, if performed, a gap having a uniform size between base substrate 10 and SiC substrate 20, which are to face each other. Accordingly, in a below-described step (S40), uniformity is improved in reaction (connection) at the connection surface. This allows base substrate 10 and SiC substrate 20 to be connected to each other more securely. In order to connect base substrate 10 and the SiC substrate to each other further securely, the above-described connection surface preferably has a surface roughness Ra of less than 100 nm, more preferably, less than 50 nm. Further, by setting surface roughness Ra of the connection surface at less than 10 nm, more secure connection can be achieved.

Meanwhile, step (S20) may be omitted, i.e., step (S30) may be performed without polishing the main surfaces of base substrate 10 and SiC substrate 20, which are to be brought into contact with each other. This reduces manufacturing cost of silicon carbide substrate 1. Further, for removal of damaged layers located in surfaces formed by slicing upon fabrication of base substrate 10 and SiC substrate 20, a step of removing the damaged layers may be performed by, for example, etching instead of step (S20) or after step (S20), and then step (S30) described below may be performed.

Next, a stacking step is performed as step (S30). In this step (S30), referring to FIG. 1, SiC substrate 20 is placed on and in contact with main surface 10A of base substrate 10, thereby fabricating a stacked substrate. Here, in this step (S30), main surface 20A of SiC substrate 20 opposite to base substrate 10 may have an off angle of not less than 50° and not more than 65° relative to the {0001} plane. In this way, silicon carbide substrate 1 can be readily manufactured in which main surface 20A of SiC layer 20 has an off angle of not less than 50° and not more than 65° relative to the {0001} plane. Further, in step (S30), the off orientation of main surface 20A forms an angle of 5° or less relative to the <1-100> direction. This facilitates formation of an epitaxial growth layer on silicon carbide substrate 1 (main surface 20A) to be fabricated. Further, in step (S30), main surface 20A may have an off angle of not less than −3° and not more than 5° relative to the {03-38} plane in the <1-100> direction. This further improves channel mobility when fabricating a MOSFET using silicon carbide substrate 1 to be manufactured.

On the other hand, in step (S30), the off orientation of main surface 20A may form an angle of 5° or smaller relative to the <11-20> direction. This facilitates formation of an epitaxial growth layer on silicon carbide substrate 1 to be fabricated.

Next, as step (S40), a connecting step is performed. In this step (S40), stacked substrate 2 is heated to fall within a range of temperature equal to or higher than the sublimation temperature of silicon carbide constituting base substrate 10 for example, so as to connect base substrate 10 and SiC substrate 20 to each other. Accordingly, referring to FIG. 3, a connected substrate 3 is obtained. Here, for each of base substrate 10 and SiC substrate 20 prepared in step (S10), it is difficult to prepare a substrate having no deformation such as a warpage and having a perfect planar shape. Hence, in stacked substrate 2 fabricated in step (S30), base substrate 10 and SiC substrate 20 are not entirely and completely in close contact with each other. Stacked substrate 2 often has a region in which they are in contact with each other and a region in which they are not in contact with each other. As a result, in step (S30), voids 30 are formed in the vicinity of a connection interface 15 between base substrate 10 and SiC substrate 20.

Next, as a step (S50), a void transferring step is performed. In step (S50), connected substrate 3 is heated to form a temperature difference between base substrate 10 and SiC substrate 20. Specifically, for example, connected substrate 3 is heated to cause base substrate 10 to have a temperature higher than that of SiC substrate 20.

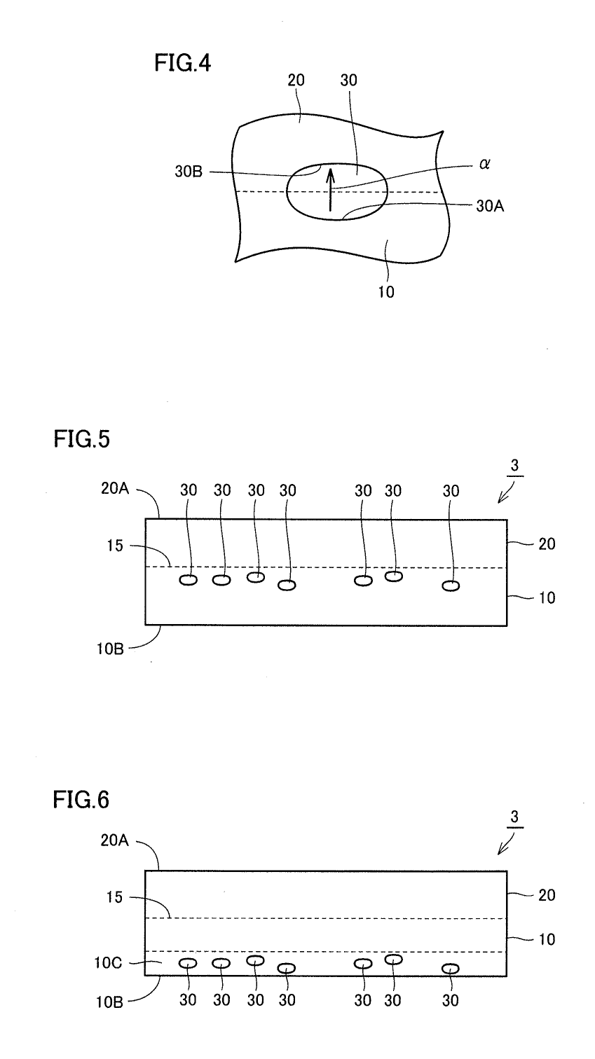

On this occasion, referring to FIG. 4, in each void 30, silicon carbide is sublimated which constitutes a region along an inner wall 30A of base substrate 10 having the higher temperature. The silicon carbide thus sublimated is transferred along an arrow a, and then reaches and is solidified on an inner wall 30B of SiC substrate 20 having the lower temperature. Accordingly, as shown in FIG. 5, voids 30 are transferred in the direction of base substrate 10. By maintaining this state, as shown in FIG. 6, voids 30 are transferred to the vicinity of main surface 10B of base substrate 10 opposite to SiC substrate 20.

Here, in step (S50), the heating may be performed to cause either one of base substrate 10 and SiC substrate 20 to have a higher temperature. However, in the present embodiment, connected substrate 3 is heated to cause base substrate 10 to have a temperature higher than that of SiC substrate 20 in order to transfer voids 30 in the direction of base substrate 10 to suppress influence of voids 30 over quality and yield of SiC substrate 20. Further, connected substrate 3 is heated in a crucible or on a susceptor, each of which is made of graphite or is made of graphite and has a surface coated with tantalum carbide, for example. On this occasion, as pressure of atmosphere is lower, voids 30 are transferred at a faster rate. Hence, for improved manufacturing efficiency, it is desirable to reduce the pressure of the atmosphere, specifically, it is desirable to render the pressure smaller than the atmospheric pressure. Exemplary atmosphere employed upon the heating is noble gas (such as argon), nitrogen, or the like. Further, by heating stacked substrate 2 with the temperature difference being formed as described above, step (S40) and step (S50) may be performed simultaneously.

Next, as a step (S60), a void removing step is performed. In step (S60), voids 30 are removed by removing a region including the main surface of the more highly heated one of base substrate 10 and SiC substrate 20 in step (S50). The main surface of the substrate is located opposite to the other substrate. Specifically, for example, in the present embodiment, referring to FIG. 6, a region 10C including main surface 10B of base substrate 10 opposite to SiC substrate 20 is removed, thereby removing voids 30. By the procedure described above, silicon carbide substrate 1 shown in FIG. 7 in the present embodiment is completed.

Here, according to the above-described process, silicon carbide substrate 1 can have a desired shape and size by selecting the shape or the like of base substrate 10. This contributes to improved efficiency in manufacturing semiconductor devices. Further, silicon carbide substrate 1 manufactured through such a process utilizes SiC substrate 20 formed of high-quality silicon carbide single-crystal and having not been used because it cannot be processed into a desired shape and the like conventionally. Using such a silicon carbide substrate, semiconductor devices can be manufactured, thereby effectively using silicon carbide single-crystal. As such, according to the method for manufacturing silicon carbide substrate 1 in the present embodiment, there can be manufactured a silicon carbide substrate 1 that allows for reduced cost of manufacturing semiconductor devices using the silicon carbide substrate.

Further, according to the above-described process, voids 30 formed in the vicinity of connection interface 15 between base substrate 10 and SiC substrate 20 are transferred in step (S50), and then are removed in step (S60). Accordingly, voids 30 are reduced in silicon carbide substrate 1, thus suppressing increased resistivity of the substrate, decreased strength of the substrate, and the like, each of which is otherwise caused by existence of voids 30.

Here, in step (S50) described above, main surface 10B of base substrate 10 opposite to SiC substrate 20 is preferably heated to fall within a temperature range of not less than 1500° C. and not more than 3000° C. With the heating temperature set at 1500° C. or greater, voids 30 are transferred at a fast rate, thereby achieving efficient transfer of voids 30. On the other hand, with the heating temperature set at 3000° C. or smaller, damages can be prevented from occurring upon etching SiC substrate 20.

It should be noted that the above-described method for manufacturing the silicon carbide substrate may further include a step of polishing the main surface of SiC substrate 20 that corresponds to main surface 20A of SiC substrate 20 opposite to base substrate 10 in the stacked substrate. This allows a high-quality epitaxial growth layer to be formed on main surface 20A of SiC layer 20 (SiC substrate 20) opposite to base substrate 10. As a result, a semiconductor device can be manufactured which includes the high-quality epitaxial growth layer as an active layer, for example. Namely, by employing such a step, silicon carbide substrate 1 can be obtained which allows for manufacturing of a high-quality semiconductor device including the epitaxial layer formed on SiC layer 20. Here, main surface 20A of SiC substrate 20 may be polished after base substrate 10 and SiC substrate 20 are connected to each other. Alternatively, there may be polished in advance the main surface of SiC substrate 20 that is opposite to base substrate 10 and that is to be main surface 20A in stacked substrate 2, thus performing the polishing before the step of fabricating stacked substrate 2.

Referring to FIG. 7, silicon carbide substrate 1 obtained according to the above-described manufacturing method includes base layer 10 made of silicon carbide, and SiC layer 20 made of single-crystal silicon carbide different from that of base layer 10. Here, the expression “SiC layer 20 is made of single-crystal silicon carbide different from that of base layer 10” encompasses a case where base layer 10 is made of silicon carbide, which is not of single-crystal such as polycrystal silicon carbide or amorphous silicon carbide; and a case where base layer 10 is made of single-crystal silicon carbide different in crystal from that of SiC layer 20. The expression “base layer 10 and SiC layer 20 are made of silicon carbide different in crystal” refers to, for example, a state in which a defect density in one side relative to a boundary between base layer 10 and SiC layer 20 is different from that in the other side. In this case, the defect densities may be discontinuous at the boundary.

Further, in the method for manufacturing silicon carbide substrate 1 in the present embodiment, in step (S40), the stacked substrate may be heated in an atmosphere obtained by reducing pressure of the atmospheric air. This reduces manufacturing cost of silicon carbide substrate 1. Further, in step (S50), the connected substrate may be heated in an atmosphere obtained by reducing pressure of the atmospheric air. This reduces manufacturing cost of silicon carbide substrate 1.

Further, in step (S40) of the method for manufacturing silicon carbide substrate 1 in the present embodiment, stacked substrate 2 may be heated under a pressure higher than 10⁻¹ Pa and lower than 10⁴ Pa. This can accomplish the above-described connection using a simple device, and provide an atmosphere for accomplishing the connection for a relatively short time. As a result, the manufacturing cost of silicon carbide substrate 1 can be reduced. Further, in step (S50), connected substrate 3 may be heated under a pressure higher than 10⁻¹ Pa and lower than 10⁴ Pa. This can accomplish the above-described transfer of voids 30 using a simple device, and provide an atmosphere for accomplishing the transfer of voids 30 for a relatively short time. As a result, the manufacturing cost of silicon carbide substrate 1 can be reduced.

Here, in the stacked substrate fabricated in step (S30), the gap formed between base substrate 10 and SiC substrate 20 is preferably 100 μm or smaller. Accordingly, in step (S40), uniform connection between base substrate 10 and SiC substrate 20 can be achieved.

Further, heating temperature for the stacked substrate in step (S40) is preferably not less than 1800° C. and not more than 2500° C. If the heating temperature is lower than 1800° C., it takes a long time to connect base substrate 10 and SiC substrate 20, which results in decreased efficiency in manufacturing silicon carbide substrate 1. On the other hand, if the heating temperature exceeds 2500° C., surfaces of base substrate 10 and SiC substrate 20 become rough, which may result in generation of a multiplicity of crystal defects in silicon carbide substrate 1 to be fabricated. In order to improve efficiency in manufacturing while restraining generation of defects in silicon carbide substrate 1, the heating temperature for the stacked substrate in step (S40) is preferably set at not less than 1900° C. and not more than 2100° C.

Further, the atmosphere upon the heating in step (S40) may be inert gas atmosphere. In the case where the atmosphere is the inert gas atmosphere, the inert gas atmosphere preferably contains at least one selected from a group consisting of argon, helium, and nitrogen.

### Second Embodiment

The following describes another embodiment of the present invention, i.e., a second embodiment. A method for manufacturing a silicon carbide substrate in the second embodiment is performed in basically the same manner as in the first embodiment. However, the method for manufacturing the silicon carbide substrate in the second embodiment is different from that of the first embodiment in terms of arrangement of SiC substrates.

In the method for manufacturing the silicon carbide substrate in the second embodiment, referring to FIG. 1, the substrate preparing step is performed as step (S10) as with the first embodiment. In this step (S10), a base substrate 10 and SiC substrates 20 are prepared. Thus, in the present embodiment, the plurality of SiC substrates 20 are prepared.

Next, step (S20) is performed in the same way as in the first embodiment, as required. Thereafter, the stacking step is performed as step (S30). In this step (S30), referring to FIG. 8, when viewed in a planar view, the plurality of SiC substrates 20 prepared in step (S10) are arranged side by side in contact with main surface 10A of base substrate 10. On this occasion, the plurality of SiC substrates 20 are preferably arranged in the form of a matrix such that adjacent SiC substrates 20 are in contact with each other on base substrate 10.

Then, as step (S40), the connecting step is performed in the same way as in the first embodiment to obtain connected substrate 3 (see FIG. 9). On this occasion, as with the first embodiment, voids 30 are formed in the vicinity of a connection interface 15 between base substrate 10 and each SiC substrate 20. Further, in the present embodiment, a void 31 is formed in the vicinity of a connection interface 25 between SiC substrates 20.

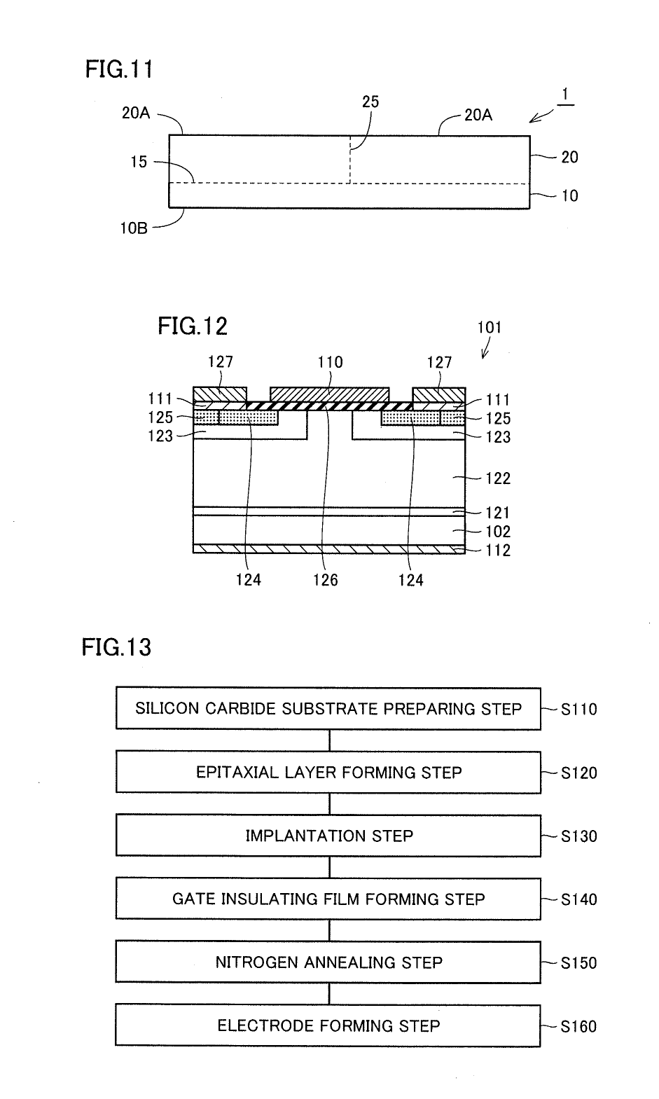

Next, as with the first embodiment, the void transferring step is performed as step (S50). Accordingly, as shown in FIG. 10, voids 30 formed in the vicinity of connection interface 15 reaches a vicinity of main surface 10B of base substrate 10 opposite to SiC substrate 20. Further, void 31 formed in the vicinity of connection interface 25 between SiC substrates 20 also reaches the vicinity of main surface 10B. Then, as with the first embodiment, step (S60) is performed, thereby completing silicon carbide substrate 1 shown in FIG. 11 in the present embodiment. Because the plurality of SiC substrates 20 are used, silicon carbide substrate 1 can be readily provided with a large diameter, thus further reducing manufacturing cost of semiconductor devices using the silicon carbide substrate.

Further, referring to FIG. 8, each of SiC substrates 20 preferably has an end surface 20C substantially perpendicular to main surface 20A of SiC substrate 20. In this way, silicon carbide substrate 1 can be readily formed. Here, for example, when end surface 20C and main surface 20A form an angle of not less than 85° and not more than 95°, it can be determined that end surface 20C and main surface 20A are substantially perpendicular to each other.

### Third Embodiment

As a third embodiment, the following describes one exemplary semiconductor device fabricated using the above-described silicon carbide substrate of the present invention. Referring to FIG. 12, a semiconductor device 101 according to the present invention is a DiMOSFET (Double Implanted MOSFET) of vertical type, and has a substrate 102, a buffer layer 121, a breakdown voltage holding layer 122, p regions 123, n⁺ regions 124, p⁺ regions 125, an oxide film 126, source electrodes 111, upper source electrodes 127, a gate electrode 110, and a drain electrode 112 formed on the backside surface of substrate 102. Specifically, buffer layer 121 made of silicon carbide is formed on the front-side surface of substrate 102 made of silicon carbide of n type conductivity. Employed as substrate 102 is the silicon carbide substrate manufactured in accordance with a method for manufacturing a silicon carbide substrate in the present invention, i.e., method inclusive of those described in the first and second embodiments. In the case where silicon carbide substrate 1 in each of the first and second embodiments is employed, buffer layer 121 is formed on SiC layer 20 of silicon carbide substrate 1. Buffer layer 121 has n type conductivity, and has a thickness of, for example, 0.5 μm. Further, impurity with n type conductivity in buffer layer 121 has a concentration of, for example, 5×10¹⁷ cm⁻³. Formed on buffer layer 121 is breakdown voltage holding layer 122. Breakdown voltage holding layer 122 is made of silicon carbide of n type conductivity, and has a thickness of 10 for example. Further, breakdown voltage holding layer 122 includes an impurity of n type conductivity at a concentration of, for example, 5×10¹⁵ cm⁻³.

Breakdown voltage holding layer 122 has a surface in which p regions 123 of p type conductivity are formed with a space therebetween. In each of p regions 123, an n⁺ region 124 is formed at the surface layer of p region 123. Further, at a location adjacent to n⁺ region 124, a p⁺ region 125 is formed. Oxide film 126 is formed to extend on n⁺ region 124 in one p region 123, p region 123, an exposed portion of breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed. Moreover, drain electrode 112 is formed on the backside surface of substrate 102, i.e., the surface opposite to its front-side surface on which buffer layer 121 is formed.

Semiconductor device 101 in the present embodiment employs, as substrate 102, the silicon carbide substrate manufactured in accordance with the method for manufacturing the silicon carbide substrate in the present invention, i.e., method inclusive of those described in the first and second embodiments. Namely, semiconductor device 101 includes: substrate 102 serving as the silicon carbide substrate; buffer layer 121 and breakdown voltage holding layer 122 both serving as epitaxial growth layers formed on and above substrate 102; and source electrodes 111 formed on breakdown voltage holding layer 122. Further, substrate 102 is manufactured in accordance with the method for manufacturing the silicon carbide substrate in the present invention. Here, as described above, the substrate manufactured in accordance with the method for manufacturing the silicon carbide substrate in the present invention allows for reduced manufacturing cost of semiconductor devices. Hence, semiconductor device 101 is manufactured with the reduced manufacturing cost.

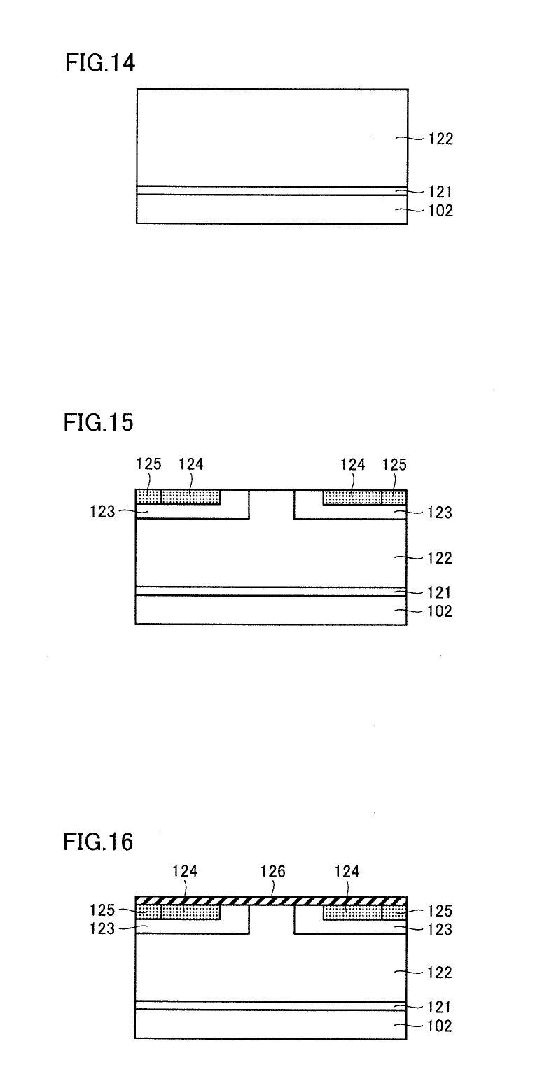

The following describes a method for manufacturing semiconductor device 101 shown in FIG. 12, with reference to FIG. 13-FIG. 17. Referring to FIG. 13, first, a silicon carbide substrate preparing step (S110) is performed. Prepared here is, for example, substrate 102, which is made of silicon carbide and has its main surface corresponding to the (03-38) plane (see FIG. 14). As substrate 102, there is prepared a silicon carbide substrate of the present invention, inclusive of silicon carbide substrate 1 manufactured in accordance with each of the manufacturing methods described in the first and second embodiments.

As substrate 102 (see FIG. 14), a substrate may be employed which has n type conductivity and has a substrate resistance of 0.02 Ωcm.

Next, as shown in FIG. 13, an epitaxial layer forming step (S120) is performed. Specifically, buffer layer 121 is formed on the front-side surface of substrate 102. Buffer layer 121 is formed on main surface 20A (see FIG. 7) of SiC layer 20 of silicon carbide substrate 1 employed as substrate 102. As buffer layer 121, an epitaxial layer is formed which is made of silicon carbide of n type conductivity and has a thickness of 0.5 μm, for example. Buffer layer 121 has a conductive impurity at a density of, for example, 5×10¹⁷ cm ⁻³. Then, on buffer layer 121, breakdown voltage holding layer 122 is formed as shown in FIG. 14. As breakdown voltage holding layer 122, a layer made of silicon carbide of n type conductivity is faulted using an epitaxial growth method. Breakdown voltage holding layer 122 can have a thickness of, for example, 10 μm. Further, breakdown voltage holding layer 122 includes an impurity of n type conductivity at a density of, for example, 5×10¹⁵ cm⁻³.

Next, as shown in FIG. 13, an implantation step (S 130) is performed. Specifically, an impurity of p type conductivity is implanted into breakdown voltage holding layer 122 using, as a mask, an oxide film formed through photolithography and etching, thereby forming p regions 123 as shown in FIG. 15. Further, after removing the oxide film thus used, an oxide film having a new pattern is formed through photolithography and etching. Using this oxide film as a mask, a conductive impurity of n type conductivity is implanted into predetermined regions to form n⁺ regions 124. In a similar way, a conductive impurity of p type conductivity is implanted to form p⁺ regions 125. As a result, the structure shown in FIG. 15 is obtained.

After such an implantation step, an activation annealing process is performed. This activation annealing process can be performed under conditions that, for example, argon gas is employed as atmospheric gas, heating temperature is set at 1700° C., and heating time is set at 30 minutes.

Next, a gate insulating film forming step (S140) is performed as shown in FIG. 13. Specifically, as shown in FIG. 16, oxide film 126 is formed to cover breakdown voltage holding layer 122, p regions 123, n⁺ regions 124, and p⁺ regions 125. As a condition for forming oxide film 126, for example, dry oxidation (thermal oxidation) may be performed. The dry oxidation can be performed under conditions that the heating temperature is set at 1200° C. and the heating time is set at 30 minutes.

Thereafter, a nitrogen annealing step (S 150) is performed as shown in FIG. 13. Specifically, an annealing process is performed in atmospheric gas of nitrogen monoxide (NO). Temperature conditions for this annealing process are, for example, as follows: the heating temperature is 1100° C. and the heating time is 120 minutes. As a result, nitrogen atoms are introduced into a vicinity of the interface between oxide film 126 and each of breakdown voltage holding layer 122, p regions 123, n⁺ regions 124, and p⁺ regions 125, which are disposed below oxide film 126. Further, after the annealing step using the atmospheric gas of nitrogen monoxide, additional annealing may be performed using argon (Ar) gas, which is an inert gas. Specifically, using the atmospheric gas of argon gas, the additional annealing may be performed under conditions that the heating temperature is set at 1100° C. and the heating time is set at 60 minutes.

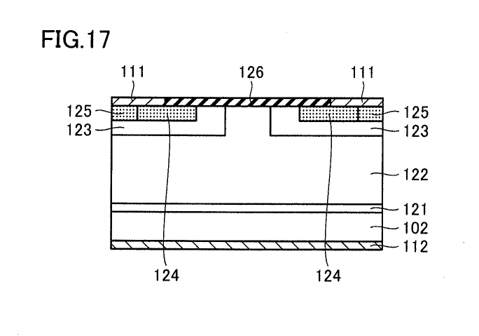

Next, as shown in FIG. 13, an electrode forming step (S160) is performed. Specifically, a resist film having a pattern is formed on oxide film 126 by means of the photolithography method. Using the resist film as a mask, portions of the oxide film above n⁺ regions 124 and p⁺ regions 125 are removed by etching. Thereafter, a conductive film such as a metal is formed on the resist film and formed in openings of oxide film 126 in contact with n⁺ regions 124 and p⁺ regions 125. Thereafter, the resist film is removed, thus removing the conductive film's portions located on the resist film (lift-off). Here, as the conductor, nickel (Ni) can be used, for example. As a result, as shown in FIG. 17, source electrodes 111 can be obtained. It should be noted that on this occasion, heat treatment for alloying is preferably performed. Specifically, using atmospheric gas of argon (Ar) gas, which is an inert gas, the heat treatment (alloying treatment) is performed with the heating temperature being set at 950° C. and the heating time being set at 2 minutes.

Thereafter, on source electrodes 111, upper source electrodes 127 (see FIG. 12) are formed. Further, gate electrode 110 (see FIG. 12) is formed on oxide film 126. Furthermore, drain electrode 112 is formed (see FIG. 12). In this way, semiconductor device 101 shown in FIG. 12 can be obtained.

It should be noted that in the third embodiment, the vertical type MOSFET has been illustrated as one exemplary semiconductor device that can be fabricated using the silicon carbide substrate of the present invention, but the semiconductor device that can be fabricated is not limited to this. For example, various types of semiconductor devices can be fabricated using the silicon carbide substrate of the present invention, such as a JFET (Junction Field Effect Transistor), an IGBT (Insulated Gate Bipolar Transistor), and a Schottky barrier diode.

Further, the third embodiment has illustrated a case where the semiconductor device is fabricated by forming the epitaxial layer, which serves as an active layer, on the silicon carbide substrate having its main surface corresponding to the (03-38) plane. However, the crystal plane that can be adopted for the main surface is not limited to this and any crystal plane suitable for the purpose of use and including the (0001) plane can be adopted for the main surface.

Further, as the main surface (main surface 20A of SiC substrate (SiC layer) 20 of silicon carbide substrate 1), there can be adopted a main surface having an off angle of not less than −3° and not more than +5° relative to the (0-33-8) plane in the <01-10> direction, so as to further improve channel mobility in the case where a MOSFET or the like is fabricated using the silicon carbide substrate. Here, the (0001) plane of single-crystal silicon carbide of hexagonal crystal is defined as the silicon plane whereas the (000-1) plane is defined as the carbon plane. Meanwhile, the “off angle relative to the (0-33-8) plane in the <01-10> direction” refers to an angle formed by the orthogonal projection of a normal line of the main surface to a flat plane defined by the <000-1> direction and the <01-10> direction serving as a reference for the off orientation, and a normal line of the (0-33-8) plane. The sign of a positive value corresponds to a case where the orthogonal projection approaches in parallel with the <01-10> direction, whereas the sign of a negative value corresponds to a case where the orthogonal projection approaches in parallel with the <000-1> direction. Further, the expression “the main surface having an off angle of not less than −3° and not more than +5° relative to the (0-33-8) plane in the <01-10> direction” indicates that the main surface corresponds to a plane, at the carbon plane side, which satisfies the above-described conditions in the silicon carbide crystal. It should be noted that in the present application, the (0-33-8) plane includes an equivalent plane, at the carbon plane side, which is expressed in a different manner due to determination of an axis for defining a crystal plane, and does not include a plane at the silicon plane side.

It should be noted that the base substrate (base layer) preferably has a diameter of 2 inches or greater, more preferably, 6 inches or greater in the method for manufacturing the silicon carbide substrate, the method for manufacturing the semiconductor device, the silicon carbide substrate, and the semiconductor device in the present invention. Further, in consideration of application thereof to a power device, silicon carbide constituting the SiC layer (SiC substrate) preferably has a polytype of 4H. In addition, each of the base substrate and the SiC substrate preferably has the same crystal structure. Moreover, a difference in thermal expansion coefficient between the base layer and the SiC layer is preferably small enough to generate no cracks in the process of manufacturing the semiconductor device using the silicon carbide substrate. Further, in each of the base substrate and the SiC substrate, variation in the thickness thereof in the plane is small, specifically, the variation of the thickness thereof is preferably 10 μm or smaller. Meanwhile, in consideration of application thereof to a vertical type device in which electric current flows in the direction of thickness of the silicon carbide substrate, the base layer preferably has an electrical resistivity of less than 50 mΩcm, more preferably, less than 10 mΩcm. Meanwhile, in order to facilitate handling thereof, the silicon carbide substrate preferably has a thickness of 300 μm or greater. Further, the heating of the stacked substrate in the step of connecting the base substrate and the SiC substrate can be performed using, for example, a resistive heating method, a high-frequency induction heating method, a lamp annealing method, or the like.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

The method for manufacturing the silicon carbide substrate, the method for manufacturing the semiconductor device, the silicon carbide substrate, and the semiconductor device in the present invention are particularly advantageously applicable to a method for manufacturing a silicon carbide substrate, a method for manufacturing a semiconductor device, a silicon carbide substrate, and a semiconductor device, each of which is required to achieve reduced manufacturing cost of a semiconductor device that employs a silicon carbide substrate.

### REFERENCE SIGNS LIST

1: silicon carbide substrate; 2: stacked substrate; 3: connected substrate; 10: base layer (base substrate); 10A, 10B: main surface; 15: connection interface; 20: SiC layer (SiC substrate); 20A, 20B: main surface; 20C: end surface; 25: connection interface; 30, 31: void; 30A, 30B: inner wall; 101: semiconductor device; 102: substrate; 110: gate electrode; 111: source electrode; 112: drain electrode; 121: buffer layer; 122: breakdown voltage holding layer; 123: p region; 124: n⁺ region; 125: p⁺ region; 126: oxide film; 127: upper source electrode.

1. A method for manufacturing a silicon carbide substrate, comprising the steps of:
preparing a base substrate made of silicon carbide and a SiC substrate made of single-crystal silicon carbide;
fabricating a stacked substrate by stacking said base substrate and said SiC substrate such that main surfaces of said base substrate and said SiC substrate are in contact with each other;
fabricating a connected substrate by heating said stacked substrate to connect said base substrate and said SiC substrate to each other;
transferring a void in a thickness direction of said connected substrate by heating said connected substrate to form a temperature difference between said base substrate and said SiC substrate, said void being formed at an interface between said base substrate and said SiC substrate in the step of fabricating said connected substrate; and
removing said void by removing a region including a main surface of one substrate of said base substrate and said SiC substrate, said one substrate being heated to have a higher temperature in the step of transferring said void, said main surface of said one substrate being opposite to the other substrate of said base substrate and said SiC substrate.

2. The method for manufacturing the silicon carbide substrate according to claim 1, wherein:
in the step of transferring said void, said connected substrate is heated to cause said base substrate to have a temperature higher than that of said SiC substrate, and
in the step of removing said void, said void is removed by removing a region including a main surface of said base substrate opposite to said SiC substrate.

3. The method for manufacturing the silicon carbide substrate according to claim 2, wherein in the step of transferring said void, the main surface of said base substrate opposite to said SiC substrate is heated to fall within a temperature range of not less than 1500° C. and not more than 3000° C.

4. The method for manufacturing the silicon carbide substrate according to claim 1, further comprising the step of smoothing the main surfaces of said base substrate and said SiC substrate before the step of fabricating said stacked substrate, the main surfaces of said base substrate and said SiC substrate being to be brought into contact with each other in the step of fabricating said stacked substrate.

5. The method for manufacturing the silicon carbide substrate according to claim 1, wherein the step of fabricating said stacked substrate is performed without polishing the main surfaces of said base substrate and said SiC substrate before the step of fabricating said stacked substrate, the main surfaces of said base substrate and said SiC substrate being to be brought into contact with each other in the step of fabricating said stacked substrate.

6. The method for manufacturing the silicon carbide substrate according to claim 1, wherein in the step of fabricating said stacked substrate, a plurality of said SiC substrates are arranged side by side on said base substrate when viewed in a planar view.

7. The method for manufacturing the silicon carbide substrate according to claim 1, wherein in the step of fabricating said stacked substrate, said SiC substrate has a main surface opposite to said base substrate and having an off angle of not less than 50° and not more than 65° relative to a {0001} plane.

8. The method for manufacturing the silicon carbide substrate according to claim 7, wherein in the step of fabricating said stacked substrate, the main surface of said SiC substrate opposite to said base substrate has an off orientation forming an angle of 5° or smaller relative to a <1-100> direction.

9. The method for manufacturing the silicon carbide substrate according to claim 8, wherein in the step of fabricating said stacked substrate, the main surface of said SiC substrate opposite to said base substrate has an off angle of not less than −3° and not more than 5° relative to a {03-38} plane in the <1-100> direction.

10. The method for manufacturing the silicon carbide substrate according to claim 7, wherein in the step of fabricating said stacked substrate, the main surface of said SiC substrate opposite to said base substrate has an off orientation forming an angle of 5° or smaller relative to a <11-20> direction.

11. The method for manufacturing the silicon carbide substrate according to claim 1, wherein in connecting said base substrate and said SiC substrate, said stacked substrate is heated in an atmosphere obtained by reducing pressure of atmospheric air.

12. The method for manufacturing the silicon carbide substrate according to claim 1, wherein in connecting said base substrate and said SiC substrate, said stacked substrate is heated under a pressure higher than 10⁻¹ Pa and lower than 10⁴ Pa.

13. A method for manufacturing a semiconductor device, comprising the steps of:
preparing a silicon carbide substrate;
forming an epitaxial growth layer on the silicon carbide substrate; and
forming an electrode on said epitaxial growth layer,
in the step of preparing the silicon carbide substrate, the silicon carbide substrate being manufactured using the method for manufacturing the silicon carbide substrate as recited in claim 1.

14. A silicon carbide substrate manufactured using the method for manufacturing the silicon carbide substrate as recited in claim 1.

15. A semiconductor device manufactured using the method for manufacturing the semiconductor device as recited in claim 13.
